(19) United States
(12) Patent Application Publication
(10) Pub. No.: US 2018/0363140 A1
(43) Pub. Date: Dec. 20, 2018

(54) Vacuum-coating system for coating lenses

(71) Applicant: Interglass Technology AG, Steinhausen (CH)

(72) Inventors: Roman ARNET, Ennetbuergen (CH); Lutz KOERNER, Urdorf (CH); Daniel PIOTROWSKI, Steinhausen (CH)

(73) Assignee: Interglass Technology AG, Steinhausen (CH)

(21) Appl. No.: 15/781,683

(22) PCT Filed: Dec. 19, 2016
(86) PCT No.: PCT/EP2016/081787

§ 371 Date: Jun. 5, 2018

(30) Foreign Application Priority Data
Dec. 22, 2015 (CH) 01896/15

(51) Int. Cl. C23C 16/50; C23C 16/458; H01J 37/32

(52) U.S. Cl. CPC C23C 16/50; C23C 16/458; H01J 2237/3321; H01J 37/32541; H01J 37/32568; H01J 37/32715

(57) ABSTRACT

A vacuum-coating system for coating lenses comprises a vacuum chamber, an electrode holder having one or more electrodes, and a lens holder receptacle having one or more lens holders for accommodating one lens each. A separate electrode is assigned to each lens. A surface of the electrode facing the lens is a curved surface. In an outer area, the curvature of the surface of the electrode(s) can be greater than in an inner area. The distance between the electrode and the associated lens can be adjustable.

### TECHNICAL FIELD

The invention concerns a vacuum-coating system for coating lenses.

### BACKGROUND OF THE INVENTION

It is known to produce lenses using a casting process in which a monomer is poured into a cavity bounded by two mold shells and a seal and cured, for example, by UV radiation. During curing, the monomer is polymerized and the lens is formed. The seal is then removed and the lens is separated from the two mold shells. Such manufacturing processes are known for example from EP 15202 and WO 02/087861. Also known is the production of lenses by grinding from a blank. The lens can then be provided with optical layers in immersion baths or in a vacuum coating system, e.g. with anti-reflective layers, a scratch protection layer, etc.

Such a lens is a semi-finished product from which later, for example, a lens is cut out and fitted into a frame by an optician. Such lenses are also called ophthalmic lenses.

### SHORT SUMMARY OF THE INVENTION

The invention is based on the object to provide a vacuum coating system for the coating of lenses, which produces layers with a homogeneous refractive index and a uniform thickness.

The above mentioned object is solved according to the invention by the features of claim 1. Advantageous embodiments result from the dependent claims.

The invention concerns a vacuum-coating system for the simultaneous coating of several lenses. The vacuum-coating system comprising a vacuum chamber, in which a number N of lens holders and an equal number N of electrodes are arranged so that a separate electrode is assigned to each lens. The lens and the electrode are located opposite each other. According to the invention, the surface of the electrode facing the lens is a curved surface. The curved surface comprises an inner area and an outer area, which can be adjacent or separated from each other by intermediate areas. The curvature of the surface in the outer area is at least equal, but preferably greater than in the inner area.

The surface of the electrode(s) may have an inner area and a plurality of circular rings adjacent thereto which extend concentrically to an axis of symmetry of the electrode, wherein a curvature of the surface of the electrode(s) increases in discrete steps or continuously from the centre outwards from circular ring to circular ring, wherein the outermost circular ring may but need not extend to the edge of the electrode.

Preferably, the distance between the electrode and the oppositely located lens can be adjusted.

The vacuum-coating system can be in particular a PECVD or PACVD system.

In this context, a distinction is made between two types of lenses, namely minus lenses and plus lenses. The minus lens is a lens that is thinnest in the middle and whose thickness increases continuously towards the edge. The plus lens is a lens that is thickest in the middle and whose thickness continuously decreases towards the edge.

The parts of the vacuum-coating system required for understanding the invention are explained in more detail below by means of exemplary embodiments and the drawing. For reasons of clarity of the drawings, the figures are not drawn to scale.

### DESCRIPTION OF THE DRAWING FIGURES

FIGS. 1, 2, 4, 5 show an electrode and a lens in cross-section,

FIGS. 3 and 6 show the electrodes of FIGS. 1 and 4,

FIG. 7 shows a plate with recesses for receiving electrodes, and

FIG. 8 shows a cut along the line I-I of FIG. 7.

### DETAILED DESCRIPTION OF THE INVENTION

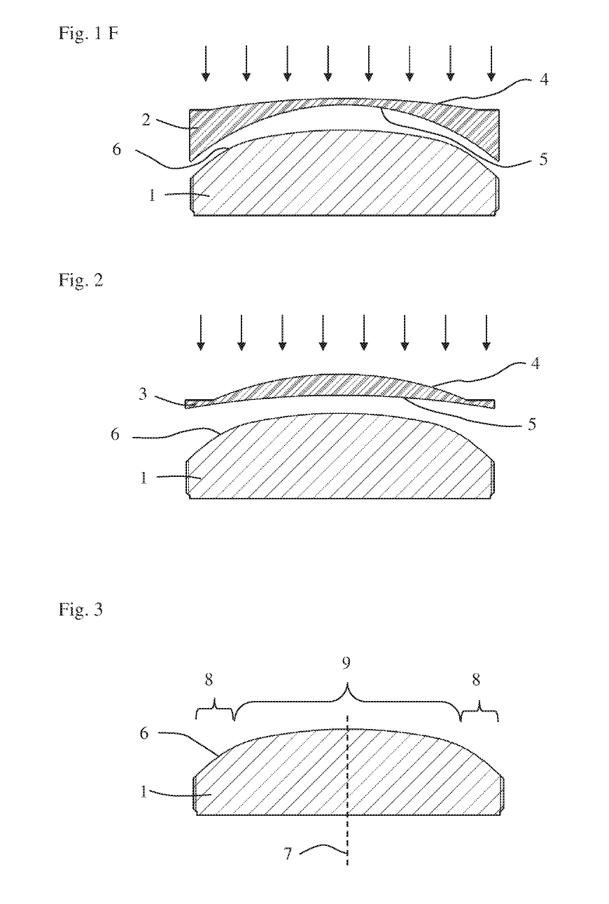

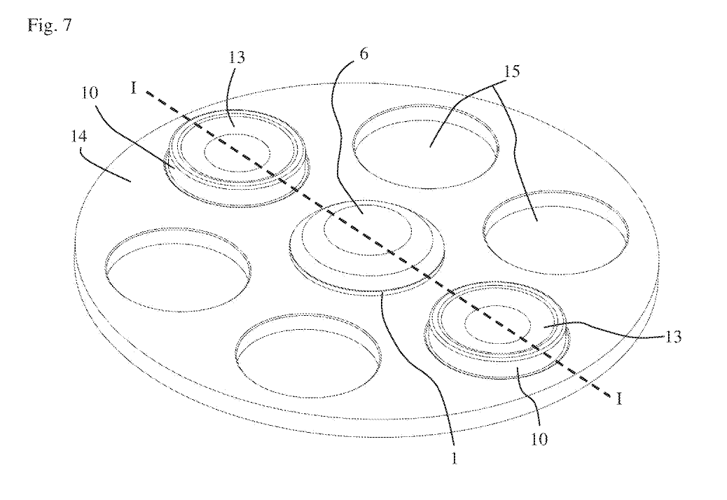

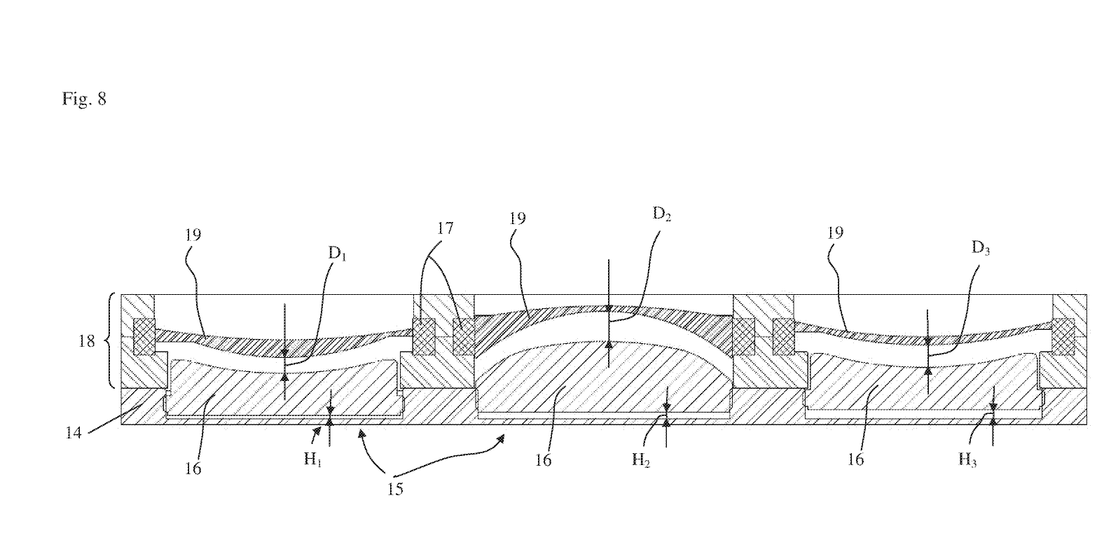

The first aspect of the invention concerns the curvature of the electrodes. This is explained using FIGS. 1-6. The second aspect of the invention concerns the adjustability of the distance between the electrode and the lens. This is explained using FIGS. 7 and 8.

FIGS. 1 and 2 show in cross-section an electrode 1 and a lens 2 or lens 3 located opposite the electrode 1. The lenses 2 and 3 have a convex surface 4 and a concave surface 5, where the convex surface 4 is to be coated, as indicated by arrows. The electrode 1 has a convex surface 6. The convex surface 6 can, but does not have to, extend to the edge of the electrode 1. The concave surface 5 of the lens 2 or the lens 3 faces the convex surface 6 of the electrode 1. The lens 2 is a minus lens. The lens 3 is a plus lens.

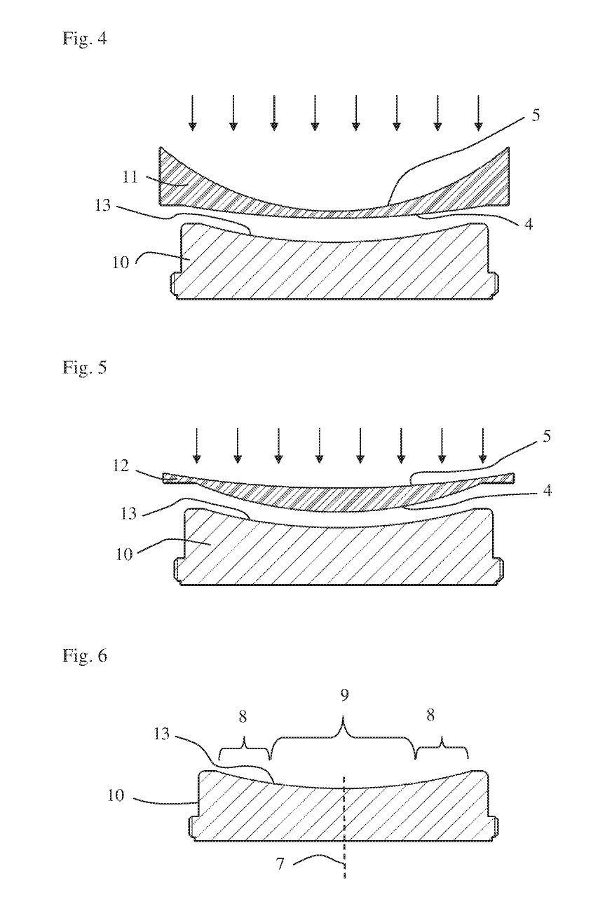

FIG. 3 shows the electrode 1 alone. The electrode 1 has a symmetry axis 7 and is typically rotationally symmetrical with respect to the symmetry axis 7. The convex surface 6 of the electrode 1 is a curved surface. In a first embodiment the curvature is uniform, i.e. the surface 6 is a spherical surface whose radius of curvature has the value r₀. In a second embodiment, the curvature of the surface 6 is greater in an outer area 8 than in an inner area 9. The curvature increases continuously or in discrete steps from the center, i.e. the axis of symmetry 7, towards the edge. For example, the inner area 9 may be a spherical surface whose radius of curvature has the value r₁, and the outer area 8 may be a spherical surface adjacent to the inner area 9 whose radius of curvature has the value r₂ with r₂<r₁. However, the surface 6 can also have the inner area 9 and several circular rings adjacent thereto, which run concentrically to the axis of symmetry 7, whereby the curvature of the surface 6 increases from the centre, i.e. from the axis of symmetry 7, outwards from circular ring to circular ring. The outermost circular ring can, but does not have to, extend to the edge of the electrode 1.

FIGS. 4 and 5 show in cross-section an electrode 10 and a lens 11 or lens 12 located opposite the electrode 10. The lenses 11 and 12 have a convex surface 4 and a concave surface 5, whereby here the concave surface 5 is to be coated, as indicated by arrows.

The electrode 10 has a concave surface 13, the concave surface 13 can but does not have to extend to the edge of the electrode 10. The convex surface 4 of the lenses 11 and 12 faces the concave surface 13 of the electrode 10. The lens 11 is a minus lens. The lens 12 is a plus lens.

FIG. 6 shows the electrode 10 alone. The electrode 10 also has an axis of symmetry 7 and is typically rotationally symmetrical with respect to the axis of symmetry 7. The concave surface 13 of the electrode 10 is a curved surface. In a first embodiment, the curvature is uniform, i.e. the surface 13 is a spherical surface whose radius of curvature has the value r₃. In a second embodiment, the curvature of the surface 13 is greater in an outer area 8 than in an inner area 9. The curvature increases continuously or in discrete steps from the center, i.e. the axis of symmetry 7, towards the edge. For example, the inner area 9 may be a spherical surface whose radius of curvature has the value r₄, and the outer area 8 may be a spherical surface adjacent to the inner area 9 whose radius of curvature has the value r₅ with r₅<r₄. However, the surface 13 can also have the inner area 9 and several circular rings adjacent thereto, which run concentrically to the axis of symmetry 7, whereby the curvature of the surface 6 increases from the centre, i.e. from the axis of symmetry 7, outwards from circular ring to circular ring. The outermost circular ring can, but does not have to, extend to the edge of electrode 10.

The formation of the electrodes 1 and 10 with curved surfaces 6 or 13, respectively, in which the curvature in an outer area 8 of the surface 6 or 13, respectively, is greater than in an inner area 9 of the surface 6 or 13, results in the distance between the electrode and the opposite lens being greater where the lens is thin and smaller where the lens is thick. In addition, the distance between the electrode and the opposite lens is adjustable. This makes it possible to set an optimum distance D for each lens. The optimum distance D for each lens is determined once in advance experimentally or using a computer program programmed for this purpose.

With only two different types of electrodes, namely electrodes 1 with a same convex surface 6 and electrodes 10 with a same concave surface 13, a large number of lenses of different geometry and thickness can be coated with layers with desired optical properties if the convex surface 6 or the concave surface 13 has a curved surface design that takes into account the variety of different lens geometries. The formation of the surface of the electrodes with a predetermined, optimised course of curvature and the individually optimisable adjustment of the distance between the lens and the electrode lead to the result that the refractive index and the thickness of the applied layer(s) seen both with the individual lenses and across all lenses which are coated in the same process in the vacuum chamber have a greater homogeneity and uniformity than could be achieved without this specific formation of the surface 6 or 13 of the electrodes 1 or 10 and without the adjustability of said distance.

It should be noted that the lenses produced are semi-finished products and that an optical element, such as a spectacle lens, for example, is cut out of the lens during further processing. For this reason, an area adjacent to the edge of the electrodes 1, 10 does not have to meet the above conditions, as the opposite lying area of the lens becomes waste anyway. This means that the mentioned outer area 8 of the surface 6 or 13 of the electrode 1 or 10 can extend to the edge of the electrode 1 or 10, but does not have to.

FIG. 7 shows in perspective view an electrode holder 14 with a predetermined number M of recesses 15 which are provided with a thread. In the example M=7. The electrode holder 14 is an electrically conductive plate. Each recess 15 is configured to accommodate one electrode. The electrodes also have a thread so that they can be screwed into the recesses 15. For reasons of clarity of the drawing, four recesses 15 are shown without electrodes, while three recesses 15 contain one electrode each, namely a recess 15 an electrode 1 with a convex surface 6 and two recesses 15 an electrode 10 with a concave surface 13.

FIG. 8 shows a cut of the electrode holder 14 along the line I-I of FIG. 7, whereby one electrode 16 is screwed into each recess 15. Lens holders 17 are arranged in a lens holder receptacle 18. The lens holder receptacle 18 is made of electrically non-conductive material and is advantageously made in two parts for easy placement and removal of the lenses 19 in or from the lens holders 17. The lens holder receptacle 18 holds the individual lens holders 17 at a predetermined equal distance from the electrode holder 14. The lens holder receptacle 18 is advantageously additionally configured as a cover that can be placed on the electrode holder 14, and thus simultaneously fulfils the task of covering as many surfaces as possible of the electrode holder 14 and the electrodes 16 which are not to be coated. The lens holder receptacle 18 can also be detachably attached to the vacuum chamber in other ways.

The threads of the recesses 15 of the electrode holder 14 are advantageously designed with markings so that the electrodes 16 can be set to certain rotational positions. Each rotational position corresponds to a different height of the electrode 16. A rotation of the electrode 16 from one rotating position to the next causes a predetermined change of the height and thus of the distance between the electrode 16 and the lens 19 held by the associated lens holder 17. With this construction, the distance between electrode 16 and lens 19 can be set with high accuracy, whereby the distance to be set or the rotational position to be set for each lens results from the corresponding lens recipe. The lenses 19 are placed in the lens holders 17 by a robot or the operator and the height of each electrode 16 is adjusted by the robot or the operator according to the corresponding lens recipe. Then the lens holder receptacle 18 is placed on the electrode holder 14 and the whole brought into the vacuum-coating system's vacuum chamber for coating.

The three lenses 19 shown in FIG. 6 are different lenses 19. The heights H₁, H₂ and H₃ of the three electrodes 16 are individually set in such a manner that the distance between the lens 19 and the associated electrode 16 has the optimum distance D₁ or D₂ or D₃. The distances D₁, D₂ and D₃ are each the distances on the symmetry axis of the electrode 16.

Possible vacuum coating processes are CVD (chemical vapor deposition) processes, in particular PECVD (plasma-enhanced chemical vapor deposition) processes and PACVD (plasma-assisted chemical vapor deposition) processes. This list is not exhaustive.

The inner wall of the vacuum chamber is electrically conductive and usually electrically earthed. It thus represents a counter electrode which is electrically insulated from the electrode holder 14 and the electrodes.

While embodiments of this invention have been shown and described, it would be apparent to those skilled in the art that more modifications than mentioned above are possible without departing from the inventive concept. The invention, therefore, is only restricted by the appended claims.

1. A vacuum-coating system configured to coat lenses, comprising
a vacuum chamber,
an electrode holder with one or more electrodes,
a lens holder receptacle with one or more lens holders for accommodating one lens each, wherein
an inner wall of the vacuum chamber represents a counter electrode which is electrically insulated from the electrode holder and the one or more electrodes,
to each lens, one of the one or more electrodes is assigned as separate electrode, and
a surface of the electrode facing the associated lens is a curved surface.

2. The vacuum-coating system of claim 1, wherein a curvature of the surface of the electrode(s) in an outer area is greater than in an inner area.

3. The vacuum-coating system of claim 1, wherein the surface of the electrode(s) has an inner area and a plurality of circular rings adjacent thereto, which run concentrically to an axis of symmetry of the electrode, wherein a curvature of the surface of the electrode(s) increases from the centre outwards from circular ring to circular ring in discrete steps or continuously, wherein the outermost circular ring may, but does not have to, extend to the edge of the electrode.

4. The vacuum-coating system of claim 1, wherein a distance between the lens and the associated electrode is adjustable.

5. The vacuum-coating system of claim 2, wherein a distance between the lens and the associated electrode is adjustable.

6. The vacuum-coating system of claim 3, wherein a distance between the lens and the associated electrode is adjustable.

7. The vacuum-coating system of claim 1, wherein the lens holder receptacle holds the lens holders at a predetermined equal distance from the electrode holder so that there is a distance between the lens and the oppositely lying surface of the associated electrode.

8. The vacuum-coating system of claim 2, wherein the lens holder receptacle holds the lens holders at a predetermined equal distance from the electrode holder so that there is a distance between the lens and the oppositely lying surface of the associated electrode.

9. The vacuum-coating system of claim 3, wherein the lens holder receptacle holds the lens holders at a predetermined equal distance from the electrode holder so that there is a distance between the lens and the oppositely lying surface of the associated electrode.

10. The vacuum-coating system of claim 4, wherein the lens holder receptacle holds the lens holders at a predetermined equal distance from the electrode holder so that there is a distance between the lens and the oppositely lying surface of the associated electrode.

11. The vacuum-coating system of claim 5, wherein the lens holder receptacle holds the lens holders at a predetermined equal distance from the electrode holder so that there is a distance between the lens and the oppositely lying surface of the associated electrode.

12. The vacuum-coating system of claim 6, wherein the lens holder receptacle holds the lens holders at a predetermined equal distance from the electrode holder so that there is a distance between the lens and the oppositely lying surface of the associated electrode.

13. The vacuum-coating system of claim 1, wherein the lens holder receptacle consists of an electrically non-conductive material.

14. The vacuum-coating system of claim 2, wherein the lens holder receptacle consists of an electrically non-conductive material.

15. The vacuum-coating system of claim 3, wherein the lens holder receptacle consists of an electrically non-conductive material.

16. The vacuum-coating system of claim 4, wherein the lens holder receptacle consists of an electrically non-conductive material.

17. The vacuum-coating system of claim 5, wherein the lens holder receptacle consists of an electrically non-conductive material.

18. The vacuum-coating system of claim 6, wherein the lens holder receptacle consists of an electrically non-conductive material.

19. The vacuum-coating system of claim 7, wherein the lens holder receptacle consists of an electrically non-conductive material.

20. The vacuum-coating system of claim 8, wherein the lens holder receptacle consists of an electrically non-conductive material.
